(19) United States
(12) Patent Application Publication
(10) Pub. No.: US 2014/0101935 A1
(43) Pub. Date: Apr. 17, 2014

(54) METHOD FOR MANUFACTURING PRINTED CIRCUIT BOARD

(71) Applicant: SAMSUNG ELECTRO-MECHANICS CO., LTD., Suwon (KR)

(72) Inventor: Oh Hi Lee, Suwon (KR)

(73) Assignee: SAMSUNG ELECTRO-MECHANICS CO., LTD., Suwon (KR)

(21) Appl. No.: 13/758,960

(22) Filed: Feb. 4, 2013

(30) Foreign Application Priority Data
Oct. 15, 2012 (KR) 10-2012-0114310

(51) Int. Cl. H05K 3/00

(52) U.S. Cl. CPC H05K 3/00
USPC 29/846

(57) ABSTRACT

Disclosed herein is a method for manufacturing a printed circuit board including: preparing a carrier member including a metal layer and a transfer circuit pattern sequentially formed on one surface thereof; preparing a base substrate having an inner layer circuit; forming an insulating layer on the base substrate; disposing the carrier member so that the transfer circuit pattern faces the insulating layer; embedding the transfer circuit pattern in the insulating layer through a heating and compressing process; and removing the carrier member, wherein the metal layer has a melting point lower than that of the transfer circuit pattern.

### CROSS REFERENCE TO RELATED APPLICATION

This application claims the benefit of Korean Patent Application No. 10-2012-0114310, filed on Oct. 15, 2012, entitled “Method for Manufacturing of Printed Circuit Board”, which is hereby incorporated by reference in its entirety into this application.

### BACKGROUND OF THE INVENTION

1. Technical Field

The present invention relates to a method for manufacturing a printed circuit board.

2. Description of the Related Art

Recently, in accordance with the development of electronic industry, a demand for multi-functional and small sized electronic component has rapidly increased.

In order to cope with this trend, a high-density circuit pattern has also been required in a printed circuit board, and various processes for implementing a fine circuit pattern has been designed and used.

The process for implementing the fine circuit pattern may be mainly divided into a semi-additive process (SAP) and an embedded process. Among them, in the case of the embedded process, the printed circuit board has a structure in which a circuit pattern is impregnated into an insulating layer, such that flatness and strength of a product may be improved, as compared to semi-additive process, and risks of generating an electric short between circuit patterns adjacent to each other and damage of the circuit pattern may be reduced. Therefore, the embedded process is appropriate for a fine circuit.

There are several methods of performing the embedded process. Among them, a method of forming a circuit pattern using a trench processing technology is a method of processing a trench on the insulating layer through a laser process or an etching process using chemicals and forming a plating layer in the trench instead of the existing method of forming a circuit pattern depending on resolving power of a dry film.

In the embedded process of forming the trench on the insulating layer and then forming the circuit pattern as described above, since an additional process of processing the trench on the insulating layer is added, the process may be complicated, such that process time and process cost may be increased.

Meanwhile, a printed circuit board according to the prior part is disclosed in U.S. Pat. No. 7,208,341.

### SUMMARY OF THE INVENTION

The present invention has been made in an effort to provide a method for manufacturing a printed circuit board capable of implementing high-density circuit pattern and reducing a risk of generating an electric short between circuit patterns adjacent to each other.

The present invention has been also made in an effort to provide a method for manufacturing a printed circuit board capable of improving connection reliability with a semiconductor device by forming a surface of a board to be flat.

The present invention has been also made in an effort to provide a method for manufacturing a printed circuit board capable of simplifying a process and reducing process cost and process time.

According to a preferred embodiment of the present invention, there is provided a method for manufacturing a printed circuit board, including: preparing a carrier member including a metal layer and a transfer circuit pattern sequentially formed on one surface thereof; preparing a base substrate; forming an insulating layer on the base substrate; disposing the carrier member so that the transfer circuit pattern faces the insulating layer; embedding the transfer circuit pattern in the insulating layer through a heating and compressing process; and removing the carrier member, wherein the metal layer has a melting point lower than that of the transfer circuit pattern.

The carrier member may be made of a metal.

The metal may be any one selected from a group consisting of a stainless steel based alloy and a titan-nickel based alloy.

The preparing of the carrier member including the metal layer and the transfer circuit pattern sequentially formed on one surface thereof may include: preparing the carrier member; forming the metal layer on the one surface of the carrier member; forming a plating resist of which a portion corresponding to the transfer circuit pattern is patterned on the metal layer; forming a plating layer on the patterned portion of the plating resist through a plating process; and removing the plating resist.

The preparing of the carrier member including the metal layer and the transfer circuit pattern sequentially formed on one surface thereof may further include forming a surface roughness on one surface of the carrier member, before the forming the metal layer on one surface of the carrier member

The forming of the surface roughness on one surface of the carrier member may be performed through a chemical polishing process, a mechanical polishing process, or a chemical-mechanical polishing process.

The surface roughness may have an average value Ra of 0.1 to 2 μm.

The carrier member may be made of a material having a thermal expansion coefficient corresponding to that of the insulating layer.

The metal layer may be made of any one selected from a group consisting of tin (Sn), cadmium (Cd), lead (Pb), bismuth (Bi), zinc (Zn), indium (In), an alloy thereof, and a combination thereof.

The insulating layer may be in a semi-hardened state.

The method for manufacturing a printed circuit board may further include forming an inner layer circuit on the base substrate, wherein a spaced distance of the inner layer circuit of the base substrate and the transfer circuit pattern embedded in the insulating layer is 5 μm or more.

The inner layer circuit may include a connecting pad for electric connection with the outside, the method for manufacturing a printed circuit board further including, after the removing of the carrier member: forming an opening part exposing the connecting pad in the insulating layer; forming a connecting via contacting the connecting pad at the opening part; and forming a solder resist layer having an open part exposing a surface of the connecting via on the insulating layer.

The removing of the carrier member may be performed by mechanically peeling off the carrier member from the insulating layer.

The method for manufacturing a printed circuit board may further include, after the removing of the carrier member, removing the metal layer remaining on the insulating layer.

The heating may be performed at a temperature same as or higher than the melting point of the metal layer and lower than the melting point of the transfer circuit pattern.

### BRIEF DESCRIPTION OF THE DRAWINGS

The above and other objects, features and advantages of the present invention will be more clearly understood from the following detailed description taken in conjunction with the accompanying drawings, in which:

FIGS. 1 to 11 are cross-sectional views sequentially showing the processes of a method for manufacturing a printed circuit board according to a preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

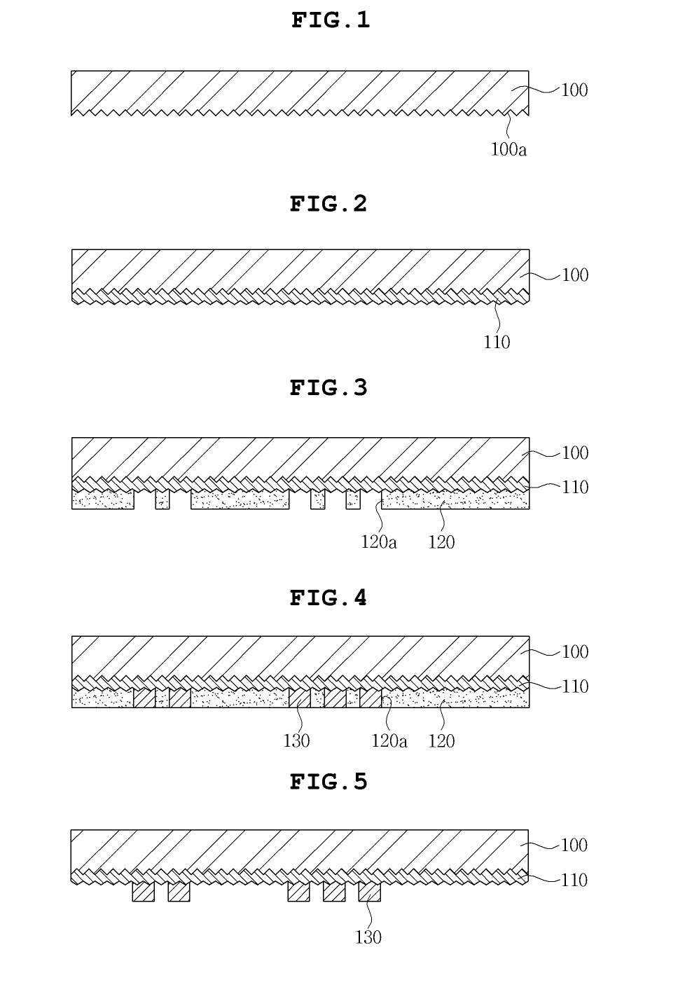

FIGS. 1 to 11 are cross-sectional views sequentially showing the processes of a method for manufacturing a printed circuit board according to a preferred embodiment of the present invention.

First, referring to FIGS. 1 to 5, a carrier member 100 including a metal layer 110 and a transfer circuit pattern 130 sequentially formed thereon is prepared.

A detailed description thereof will be provided below.

First, referring to FIG. 1, the carrier member 100 having a surface roughness 100a formed on one surface thereof is prepared.

In the present embodiment, the carrier member 100, which is a support member for forming the transfer circuit pattern 130 (See FIG. 5) embedded in an insulating layer of a printed circuit board in a subsequent process, may be made of a metal, but is not particularly limited thereto.

However, in order to form the metal layer 110 (See FIG. 2) and the transfer circuit pattern 130 on one surface of the carrier member 100 using an electro plating method in the subsequent process, a material having an electric conductivity may be preferably used, and any material having the electric conductivity in addition to the above-mention metal may be used.

Here, as a metal configuring the carrier member 100, a stainless steel based alloy, a titan-nickel based alloy, or the like, may be used, but the present invention is not particularly limited thereto.

In addition, according to the present embodiment, one surface of the carrier member 100 may be provided with the surface roughness 100a as shown in FIG. 1.

The reason is to secure adhesion between the metal layer 110 to be formed on one surface of the carrier member 100 and the carrier member 100 and between the transfer circuit pattern 130, a plating resist 120 for forming the transfer circuit pattern 130, and the carrier member 100 in the subsequence process. In the present embodiment, the surface roughness 100a may have an average value Ra of 0.1 to 2.0 μm, but is not particularly limited thereto.

However, in the case in which the surface roughness 100a formed on one surface of the carrier member 100 has an average value Ra of 0.1 μm or less, one surface of the carrier member 100 has minimal roughness to be flat such as a glass surface, such that adhesion between the metal layer 110, the plating resist 120, and the transfer circuit pattern 130 may be insufficient. Therefore, during a process of forming the metal layer 110, the plating resist 120, and the transfer circuit pattern 130, a peel-off phenomenon, that is, separation from the carrier member 100 may occur.

On the other hand, in the case in which the surface roughness 100a formed on one surface of the carrier member 100 has an average value Ra of 2.0 μm or more, it may not be easy to implement a circuit pattern having a fine pitch due to excessive roughness.

In the present embodiment, formation of the surface roughness 100a on one surface of the carrier member 100 may be performed by a chemical polishing process or mechanical polishing process, but is not particularly limited thereto.

More specifically, the surface roughness 100a may be formed by etching one surface using an electrolytic etching process, spraying an abrasive, for example, aluminum oxide (Al₂O₃) powder, or brush polishing, but is not particularly limited thereto. That is, any polishing process known in the art may be used.

Next, referring to FIG. 2, the metal layer 110 is formed on one surface of the carrier member 100, that is, the surface formed with the surface roughness 100a.

In the present embodiment, the metal layer 110 may be made of any one selected from a group consisting of tin (Sn), cadmium (Cd), lead (Pb), bismuth (Bi), zinc (Zn), indium (In), an alloy thereof, and a combination thereof, but is not particularly limited thereto.

Thereafter, referring to FIG. 3, the plating resist 120 of which a portion corresponding to the transfer circuit pattern 130 is patterned is formed on the metal layer 110.

Here, a method for forming the plating resist 120 of which the portion corresponding to the transfer circuit pattern 130 is patterned will be described in detail below.

First, after the plating resist 120 is applied onto the metal layer 110, when a mask of which a portion corresponding to the transfer circuit pattern 130 is blocked is disposed on the plating resist 120 and be exposed, the plating resist 120 of the blocked portion, that is, the portion corresponding to the transfer circuit pattern 130 is not hardened, and the plating resist 120 of the remaining portion except for the blocked portion is hardened.

Then, unhardened portion of the plating resist 120 is removed by performing a developing process.

The process described above is only an example, and all processes of forming a patterned plating resist known in the art may be used.

Next, referring to FIGS. 4 and 5, after the plating layer is formed on the patterned portion 120a of the plating resist 120 through a plating process, the carrier member 100 including the metal layer 110 and the transfer circuit pattern 130 sequentially formed on one surface thereof may be manufactured by removing the plating resist 120.

Here, the plating process may be an electro plating process and performed using the metal layer 110 as a lead line, but is not particularly limited thereto.

According to the present embodiment, the transfer circuit pattern 130 may be made of copper (Cu), but is not particularly limited thereto.

However, according to the present embodiment, the transfer circuit pattern 130 may be made of a metal having a melting point higher than that of the metal layer 110. The reason is to allow the metal layer 110 to serve as a release layer facilitating separation between the carrier member 100 and an insulating layer 160.

A detailed description thereof will be provided below.

In the subsequent process according to the present embodiment, the transfer circuit pattern 130 formed on one surface of the carrier member 100 is embedded in the insulating layer 160. Here, in order to embed the transfer circuit pattern 130 in the insulating layer 160, the insulating layer 160 should be compressed while being heated to a temperature at which the insulating layer 160 is in a semi-hardened state, wherein the heating temperature may be higher than the melting point of the metal layer 110.

For example, the insulating layer 160 is heated to a temperature at which the metal layer 110 may be melted and the transfer circuit pattern 130 may not be melted.

Therefore, the transfer circuit pattern 130 is embedded in the insulating layer 160 in a state in which the transfer circuit pattern 130 is not melted and maintains an original shape, and the metal layer 110 is melted, such that the carrier member 100 and the insulating layer 160 may maintain a state in which the carrier member 100 and the insulating layer 160 are separated from each other, and the carrier member 100 separated from the insulating layer 160 by the melted metal layer 110 may be easily peeled off when a little physical force is applied.

Since the carrier member 100 peeled off as described above may be reused later, process cost may be reduced.

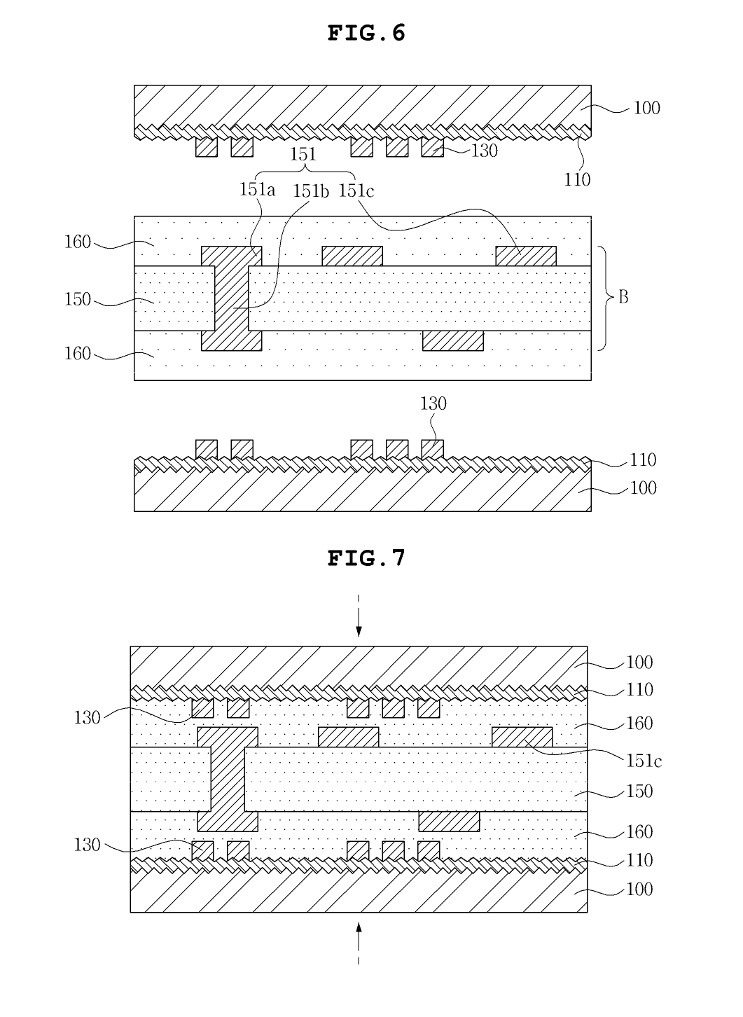

Next, referring to FIG. 6, the carrier member 100 is disposed on the insulating layer 160 so that the transferred circuit pattern 160 faces the insulating layer 160 formed on a base substrate B.

Here, although the case in which insulating layers 160 are formed on both surfaces of the base substrate B, respectively, and two carrier members 100 are disposed on each of the insulating layers 160 is shown in FIG. 6, the case is only an example, but is not particularly limited thereto. The insulating layer 160 may be formed only one surface of the base substrate B and the carrier member 100 may be disposed.

Here, the base substrate B is a printed circuit board including an inner layer circuit 151 formed on an insulating material 150 as shown in FIG. 6. Although the base substrate B is briefly shown in FIG. 6 for convenience of explanation, it may be easily appreciated by those skilled in the art that a general multi-layer printed circuit board including at least one layer circuit formed on an insulating material 150 of the base substrate B may be used.

A resin insulating material may be used as the insulating material 150. As the resin insulating material, a thermo-setting resin such as an epoxy resin, a thermo-plastic resin such as a polyimide resin, a resin having a reinforcement material such as a glass fiber or an inorganic filler impregnated in them, for example, a prepreg may be used. In addition, a thermo-setting resin, a photo-setting resin, and/or the like, may be used, but the resin insulating material is not particularly limited thereto.

The inner layer circuit 151 may include a circuit pattern 151a, a via 151c, and a connecting pad 113 as shown in FIG. 6, and the inner layer circuit 151 may be made of any material used as a conductive metal for a circuit in a circuit board field without limitation. However, in the printed circuit board, copper may be typically used.

According to the present embodiment, the inner layer circuit 151 of the base substrate B may be formed in an embossed form in which the inner layer circuit protrudes on the insulating material 151, but is not particularly limited thereto.

In addition, the insulating layer 160 formed on the base substrate B so as to cover the inner layer circuit 151 may also be made of the resin insulating material similarly to the insulating material 150 of the base substrate B, but is not particularly limited thereto.

According to the present embodiment, the insulating layer 160 may be in a semi-hardened state, but is not particularly limited thereto.

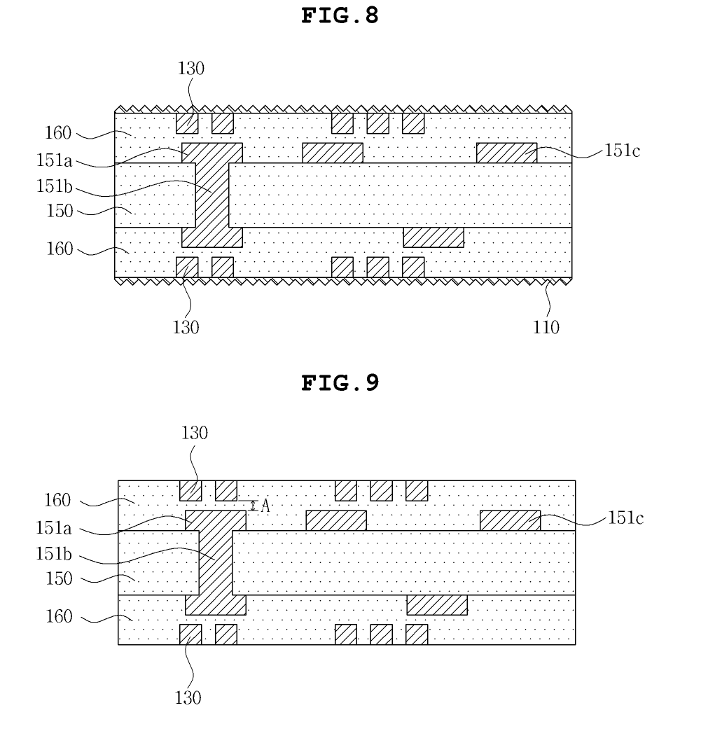

Next, referring to FIGS. 7 and 8, after the transfer circuit pattern 130 is embedded in the insulating layer 160 through a heating and compressing process, the carrier member 100 is removed.

In this case, the heating temperature may be the same as or higher than the melting point of the metal layer 110 formed on one surface of the carrier member 100 and be lower than a melting point of the transfer circuit pattern 130.

Therefore, when the carrier member 100 is compressed in an arrow direction as shown in FIG. 7, the transfer circuit pattern 130 is embedded in the insulating layer 160 in a state in which the transfer circuit pattern 130 is not melted and maintains the original shape and at the same time, the metal layer 110 is melted, such that the carrier member 100 and the insulating layer 160 may become in a state in which they are separated from each other.

Then, the carrier member 100 separated from the insulating layer 160 by the melted metal layer 110 is removed from the insulating layer 160 At this time, in order to easily remove the carrier member 100 from the insulating layer 160, a little physical force may be applied.

As described above, the carrier member 100 is not removed by etching but mechanically peeled off to thereby be removed, such that the carrier member 100 may be reused, thereby making it possible to reduce process cost.

Meanwhile, as shown in FIG. 8, after the carrier member 100 is removed, the melted metal layer 110 may remain on the insulating layer 160, and the remaining metal layer 110 may be removed through an etching process. A state in which the remaining metal layer 110 is removed is shown in FIG. 9.

Further, in the present embodiment, as the compressing process is performed in a heating state as described above, since warpage may be generated in the manufactured printed circuit board when thermal expansion coefficients of each component, that is, the base substrate B, the insulating layer 160, and the carrier member 100 are different, the carrier member 100 having a thermal expansion coefficient corresponding to those of the insulating material 150 and the insulating layer 160 of the base substrate B may be used, but is not particularly limited thereto.

In addition, according to the present embodiment, the printed circuit board may be formed so as to maintain a spaced distance A between the transfer circuit pattern 130 embedded in the insulating layer 160 and the inner layer circuit 151 of the base substrate B to be at least 5 μm.

The reason is to prevent an electric short due to insulation breakdown that may be generated by an electric signal at the time of operating the product in the case in which the spaced distance between conductor layers is 5 μm or less.

As described above, the transfer circuit pattern 130 is formed on the carrier member 100 and transferred to the insulating layer 160 to be embedded therein through the heating and compressing process, such that the process may be simplified as compared to the method of forming a trench in the insulating layer and forming a circuit pattern on the formed trench, thereby making it possible to reduce the process time and process cost.

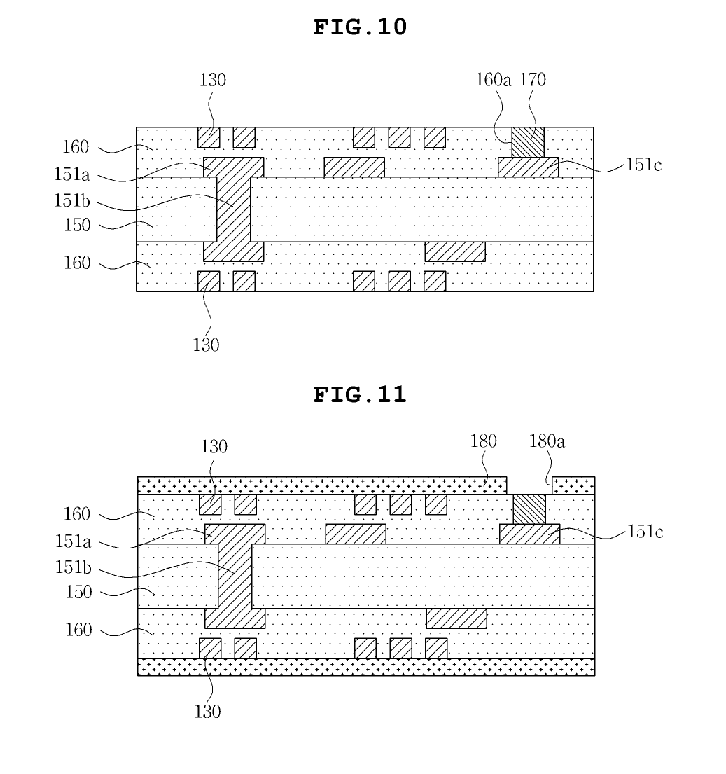

Next, referring to FIG. 10, after an opening part 160a exposing the connecting pad 151c of the inner layer circuit 151 for electric connection to an external device is formed in the insulating layer 160, a connecting via 170 contacting the connecting pad 151 is formed at the opening part 160a.

In this case, the opening part 160a in the insulating layer 160 may be formed using a laser drill, a mechanic drill, or the like, but is not particularly limited thereto.

Further, the connecting via 170 may be formed at the opening part 160a by plating or filling a conductive paste, but is not particularly limited thereto.

Next, referring to FIG. 11, a solder resist layer 180 having an open part 180a exposing a surface of the connecting via 170 is formed on the insulating layer 160.

Here, the solder resist layer 180 may serve as a protective layer protecting an outermost layer circuit, be formed for electrical insulation, and be made of, for example, solder resist ink, a solder resist film, an encapsulant, or the like, as known in the art. However, a material of the solder resist layer is particularly limited thereto.

In this case, as a method for forming the solder resist layer 180 on the board, in the case in which the solder resist is made of ink, there are a screen printing method, roll-coating method, a curtain coating method, a spray method, and the like, and in the case in which the solder resist is made of a film, there is a vacuum lamination method.

The screen printing method is a method of applying solder resist ink to the board using a screen plate. In this method, since the solder resist ink passing through the screen plate to be applied is hardened and a pattern is formed at the same time, a patterning process such as an exposure process, a developing process, a laser process, or the like is not necessary.

The roll coating method is a method of thinly applying ink having viscosity lower than that of the solder resist ink used in the screen printing method to a rubber roller to apply the ink to the board.

In addition, the curtain coating method is a method of ejecting solder resist ink having viscosity lower than that of the ink used in the roller coating method through a slit to form a film in a curtain shape and passing the board at this time to apply the ink, and the spray coating method is a method of spraying solder resist ink to apply the ink.

Further, the open part 180a may be formed using a laser drill, a mechanical drill, or the like, but is not particularly limited thereto.

The printed circuit board according to the preferred embodiment of the present invention is formed in a shape in which the outermost circuit pattern is embedded in the insulating layer through the above-mentioned processes, such that a surface of the solder resist layer for protecting the outermost circuit pattern may be formed to be flat, thereby making it possible to improve connection reliability when a semiconductor chip having a high-density input/output pad is mounted on the printed circuit board later.

Next, although not shown, a surface treatment layer may be further formed on the connecting via 170 exposed by the open part 180a.

The surface treatment layer, which is formed in order to prevent oxidation of the connecting via 170 and increase adhesion with an external device to be connected later, may be any surface treatment layer known in the art and be formed through, for example, electro gold plating, immersion gold plating, organic solderability preservative (OSP) or immersion tin plating, immersion silver plating, electroless nickel and immersion gold (ENIG), direct immersion gold (DIG) plating, hot air solder leveling (HASL), or the like.

According to the present invention, the printed circuit board is formed in a shape in which the outermost circuit is embedded, such that the surface of the board may be flat, thereby making it possible to improve connection reliability with the semiconductor device.

In addition, according to the present invention, the metal layer having the melting point lower than that of the circuit pattern and serving as the release layer is formed on one surface of the carrier member, such that since the carrier member may be removed by the mechanical peeling process rather than the etching process, the carrier member may be reused, thereby making it possible to reduce process cost.

Further, according to the present invention, the circuit pattern is formed on the carrier member and transferred to the insulating layer to be embedded therein through the compressing process, such that the process may be simplified and the process time may be reduced, as compared to the method of forming a trench to form the embedded circuit pattern according to the prior art.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A method for manufacturing a printed circuit board comprising:
preparing a carrier member including a metal layer and a transfer circuit pattern sequentially formed on one surface thereof;
preparing a base substrate;
forming an insulating layer on the base substrate;
disposing the carrier member so that the transfer circuit pattern faces the insulating layer;
embedding the transfer circuit pattern in the insulating layer through a heating and compressing process; and
removing the carrier member,
wherein the metal layer has a melting point lower than that of the transfer circuit pattern.

2. The method for manufacturing a printed circuit board as set forth in claim 1, wherein the carrier member is made of a metal.

3. The method for manufacturing a printed circuit board as set forth in claim 2, wherein the metal is any one selected from a group consisting of a stainless steel based alloy and a titan-nickel based alloy.

4. The method for manufacturing a printed circuit board as set forth in claim 1, wherein the preparing of the carrier member including the metal layer and the transfer circuit pattern sequentially formed on one surface thereof includes:
preparing the carrier member;
forming the metal layer on the one surface of the carrier member;
forming a plating resist of which a portion corresponding to the transfer circuit pattern is patterned on the metal layer;
forming a plating layer on the patterned portion of the plating resist through a plating process; and
removing the plating resist.

5. The method for manufacturing a printed circuit board as set forth in claim 4, wherein the preparing of the carrier member including the metal layer and the transfer circuit pattern sequentially formed on one surface thereof further includes forming a surface roughness on one surface of the carrier member, before the forming the metal layer on one surface of the carrier member.

6. The method for manufacturing a printed circuit board as set forth in claim 5, wherein the forming of the surface roughness on one surface of the carrier member is performed through a chemical polishing process, a mechanical polishing process, or a chemical-mechanical polishing process.

7. The method for manufacturing a printed circuit board as set forth in claim 5, wherein the surface roughness has an average value Ra of 0.1 to 2.0 μm.

8. The method for manufacturing a printed circuit board as set forth in claim 1, wherein the carrier member is made of a material having a thermal expansion coefficient corresponding to that of the insulating layer.

9. The method for manufacturing a printed circuit board as set forth in claim 1, wherein the metal layer is made of any one selected from a group consisting of tin (Sn), cadmium (Cd), lead (Pb), bismuth (Bi), zinc (Zn), indium (In), an alloy thereof, and a combination thereof.

10. The method for manufacturing a printed circuit board as set forth in claim 1, wherein the insulating layer is in a semi-hardened state.

11. The method for manufacturing a printed circuit board as set forth in claim 1, wherein the preparing a base substrate further comprising forming an inner layer circuit on the base substrate,
wherein a spaced distance of the inner layer circuit of the base substrate and the transfer circuit pattern embedded in the insulating layer is 5 μm or more.

12. The method for manufacturing a printed circuit board as set forth in claim 11, wherein the inner layer circuit includes a connecting pad for electric connection with the outside,
the method for manufacturing a printed circuit board further comprising, after the removing of the carrier member:
forming an opening part exposing the connecting pad in the insulating layer;
forming a connecting via contacting the connecting pad at the opening part; and
forming a solder resist layer having an open part exposing a surface of the connecting via on the insulating layer.

13. The method for manufacturing a printed circuit board as set forth in claim 1, wherein the removing of the carrier member is performed by mechanically peeling off the carrier member from the insulating layer.

14. The method for manufacturing a printed circuit board as set forth in claim 1, further comprising, after the removing of the carrier member, removing the metal layer remaining on the insulating layer.

15. The method for manufacturing a printed circuit board as set forth in claim 1, wherein the heating is performed at a temperature same as or higher than the melting point of the metal layer and lower than the melting point of the transfer circuit pattern.
